(19) United States
(12) Patent Application Publication
(10) Pub. No.: US 2025/0357361 A1
(43) Pub. Date: Nov. 20, 2025

(54) SEMICONDUCTOR DEVICE

(71) Applicant: Mitsubishi Electric Corporation, Tokyo (JP)

(72) Inventors: Kazuya KONISHI, Tokyo (JP); Kohei ONDA, Tokyo (JP); Kohei SAKO, Tokyo (JP); Kakeru OTSUKA, Tokyo (JP); Masanori TSUKUDA, Tokyo (JP)

(73) Assignee: Mitsubishi Electric Corporation, Tokyo (JP)

(21) Appl. No.: 18/991,341

(22) Filed: Dec. 20, 2024

(30) Foreign Application Priority Data
May 16, 2024 (JP) 2024-080264

(51) Int. Cl. H01L 23/552; H10D 12/00; H10D 64/23; H10D 64/27

(52) U.S. Cl. CPC H01L 23/552; H10D 12/481; H10D 64/232; H10D 64/516; H10D 64/518

(57) ABSTRACT

An upper electrode is separated from a lower electrode inside a trench by an intermediate insulating film. A first resistor is connected between the upper electrode and the gate electrode. A second resistor is connected between the lower electrode and the gate electrode. Gate-emitter capacitance of the lower electrode is smaller than gate-emitter capacitance of the upper electrode.

### BACKGROUND OF THE INVENTION

### Field

The present disclosure relates to a semiconductor device.

### Background

To reduce switching loss of an insulated gate bipolar transistor (IGBT), it is effective to increase switching speed. A problem of increasing the speed is that electromagnetic noise occurs. It has been reported that noise correlates with an IC peak at a low current (see, for example, Non Patent Literature 1). The Ic peak depends on overshoot of a gate voltage Vge upon turn-on, and Vge increases as a displacement current (Idis=Cgc×dV/dt) is higher and Cge is smaller. Here, Cgc is gate-collector capacitance, and Cge is gate-emitter capacitance. It is therefore necessary to decrease a Cgc/Cge ratio to reduce electromagnetic noise.

Non Patent Literature 1: K. Nishi, T. Takahashi, and A. Narazaki, “Analysis the complex tradeoff among Eon-VCEsat-SCSOA and EMI noise through the single chip evaluation method,” in Proc. 31st Int. Symp. Power Semiconductor Devices ICs (ISPSD), May 2019, pp. 475-478

### SUMMARY

### Technical Problem

However, a structure of an IGBT capable of sufficiently reducing electromagnetic noise has not been proposed.

The present disclosure has been made to solve the problem as described above, and an object thereof is to provide a semiconductor device capable of sufficiently reducing electromagnetic noise.

### Solution to Problem

A semiconductor device according to the present disclosure includes: a semiconductor substrate including a drift layer of a first conductive type, a base layer of second conductive type formed on the drift layer, a source layer of a first conductive type formed on the base layer, and a collector layer of second conductive type formed below the drift layer; an emitter electrode formed on an upper surface of the semiconductor substrate and connected to the base layer and the source layer; a gate electrode formed on the upper surface of the semiconductor substrate; a collector electrode formed on a lower surface of the semiconductor substrate and connected to the collector layer; a lower electrode formed inside a trench penetrating the source layer and the base layer from the upper surface of the semiconductor substrate via a lower gate insulating film; an upper electrode formed inside the trench via an upper gate insulating film, positioned above the lower electrode and separated from the lower electrode by an intermediate insulating film; a first resistor connected between the upper electrode and the gate electrode; and a second resistor connected between the lower electrode and the gate electrode, wherein gate-emitter capacitance of the lower electrode is smaller than gate-emitter capacitance of the upper electrode.

### Advantageous Effects of Invention

In the present disclosure, the upper electrode is separated from the lower electrode by the intermediate insulating film inside the trench. The first resistor is connected between the upper electrode and the gate electrode. The second resistor is connected between the lower electrode and the gate electrode. Gate-emitter capacitance of the lower electrode is smaller than gate-emitter capacitance of the upper electrode. This results in making it possible to sufficiently reduce electromagnetic noise in the structure of the IGBT.

### BRIEF DESCRIPTION OF DRAWINGS

FIG. 1 is a cross-sectional view illustrating a semiconductor device according to a first embodiment.

FIG. 2 is a view indicating temporal change of Vce, Ic and Vge upon turn-on of the semiconductor device according to the first embodiment.

FIG. 3 is a view indicating a relationship between Cge2/Cge1 and the Ic peak.

FIG. 4 is a cross-sectional view illustrating a relationship of thicknesses of the insulating films of the semiconductor device according to the first embodiment.

FIG. 5 is a view indicating a relationship between the thickness of the lower gate insulating film/a thickness of the upper gate insulating film and Cge of the lower electrode/Cge of the upper electrode.

FIG. 6 is a view indicating a relationship between the thickness of the lower gate insulating film/the thickness of the upper gate insulating film and the Ic peak.

FIG. 7 is a cross-sectional view illustrating a relationship between a length of the carrier accumulation layer and a length of the drift layer in the semiconductor device according to the first embodiment.

FIG. 8 is a cross-sectional view illustrating a relationship between the lengths of the lower electrode and the upper electrode and a depth of the base layer in the semiconductor device according to the first embodiment.

FIG. 9 is a cross-sectional view illustrating a semiconductor device according to a second embodiment.

FIG. 10 is a top view illustrating a semiconductor device according to a third embodiment.

FIG. 11 is a cross-sectional view illustrating a cross-section along I-II and a cross-section along III-IV in FIG. 10.

FIG. 12 is a top view illustrating a modification of the semiconductor device according to the third embodiment.

FIG. 13 is a cross-sectional view illustrating a cross-section along I-II and a cross-section along III-IV in FIG. 12.

FIG. 14 is a view illustrating a semiconductor device according to a fourth embodiment.

FIG. 15 is a cross-sectional view illustrating a semiconductor device according to a fifth embodiment.

FIG. 16 is a cross-sectional view illustrating a semiconductor device according to a sixth embodiment.

FIG. 17 is a cross-sectional view illustrating a semiconductor device according to a seventh embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

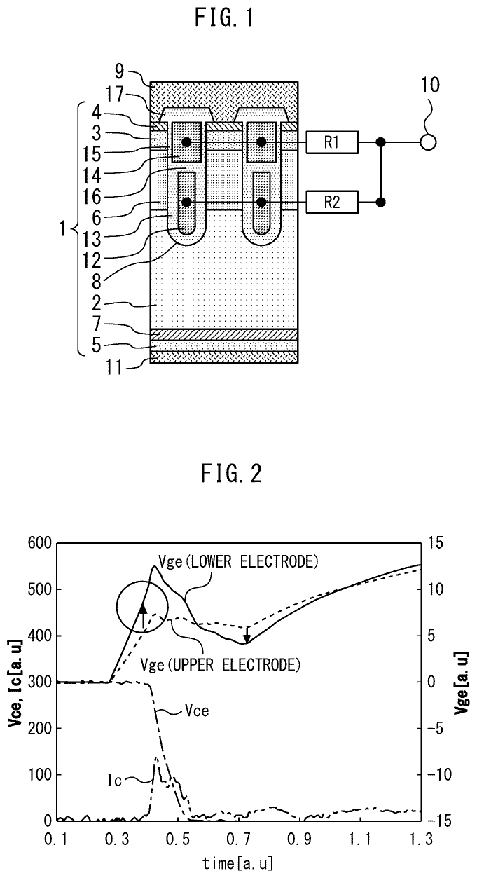

FIG. 1 is a cross-sectional view illustrating a semiconductor device according to a first embodiment. A semiconductor substrate 1 includes at least a first conductive type drift layer 2, a second conductive type base layer 3 formed on the drift layer 2, a first conductive type source layer 4 formed on part of the base layer 3, and a second conductive type collector layer 5 formed below the drift layer 2. A first conductive type carrier accumulation layer 6 is formed between the drift layer 2 and the base layer 3. A first conductive type buffer layer 7 is formed between the drift layer 2 and the collector layer 5. The carrier accumulation layer 6 and the buffer layer 7 have higher impurity concentration than that of the drift layer 2. For example, while the first conductive type is an n type, and the second conductive type is a p type, the conductive types may be inverse to each other. A plurality of trenches 8 that penetrate the source layer 4 and the base layer 3 from an upper surface of the semiconductor substrate 1 are formed side-by-side.

An emitter electrode 9 is formed on the upper surface of the semiconductor substrate 1 and is connected to the base layer 3 and the source layer 4. A gate electrode 10 is also formed on the upper surface of the semiconductor substrate 1. A collector electrode 11 is formed on a lower surface of the semiconductor substrate 1 and is connected to the collector layer 5. A lower electrode 12 is formed inside each of the trenches 8 via a lower gate insulating film 13. An upper electrode 14 is formed inside each of the trenches 8 via an upper gate insulating film 15, positioned above the lower electrode 12 and separated from the lower electrode 12 by an intermediate insulating film 16. An interlayer dielectric 17 is formed on the upper electrode 14 and separates the upper electrode 14 from the emitter electrode 9.

The intermediate insulating film 16 separates the upper electrode 14 from the lower electrode 12 inside the trench 8 as described above, and thus, gate-emitter capacitance Cge of the both electrodes can be made different from each other. While the upper electrode 14 faces the base layer 3 connected to the emitter electrode 9, and thus, Cge becomes great, the lower electrode 12 does not face the base layer 3, and thus, Cge becomes small.

Further, a first resistor R1 is connected between the upper electrode 14 and the gate electrode 10, and a second resistor R2 is connected between the lower electrode 12 and the gate electrode 10. This enables voltages of the upper electrode 14 and the lower electrode 12 to be individually controlled by the respective gate capacitance. Thus, a thickness of a gate oxide film of each electrode, and the like, are adjusted so that Cge of the lower electrode 12 becomes smaller than Cge of the upper electrode 14. This increases charging speed of capacitance of the lower electrode 12.

FIG. 2 is a view indicating temporal change of Vce, Ic and Vge upon turn-on of the semiconductor device according to the first embodiment. The charging speed of the capacitance of the lower electrode 12 is higher as described above, and thus, there is a period during which a voltage of the lower electrode 12 is higher than a voltage of the upper electrode 14 during a current increase period upon turn-on. There is a period during which the voltage of the lower electrode 12 is lower than the voltage of the upper electrode 14 during a miller period after the current increase period.

If the voltage of the lower electrode 12 becomes higher, a potential of a mesa portion placed between the lower electrodes 12 of the adjacent trenches 8 in a lateral direction also increases. Cgc is a serial connection of capacitance of the gate oxide film and capacitance of a depletion layer, and if the potential increases and the depletion layer extends, Cgc is decreased. Thus, a displacement current to the upper electrode 14 can be reduced, which makes the Ic peak smaller. This results in making it possible to sufficiently reduce electromagnetic noise in the structure of the IGBT.

Note that the electromagnetic noise is caused by increase of the Ic peak as a result of the displacement current becoming greater due to a hole and is a problem that occurs in the IGBT in which a large amount of holes flows. On the other hand, in an MOSFET, increase of the Ic peak does not prominently occur, and thus, even if the structure of the present embodiment is applied to the MOSFET, the Ic peak cannot be sufficiently made smaller.

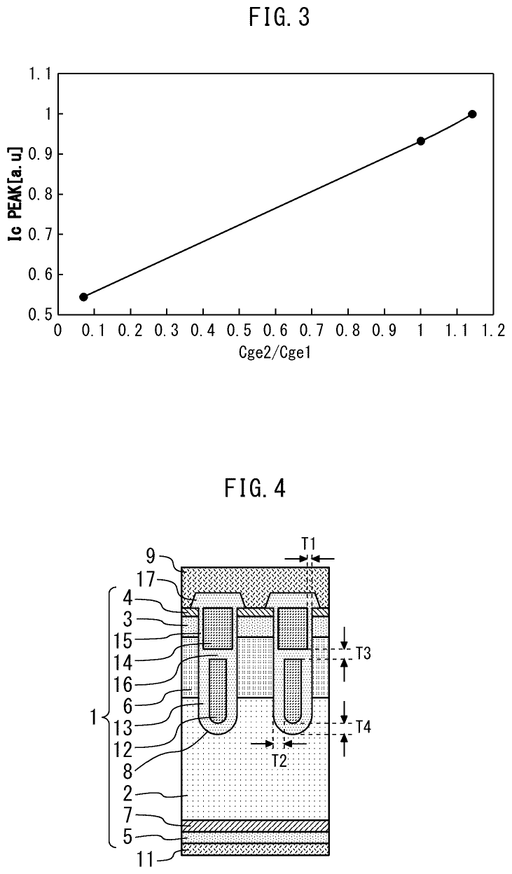

FIG. 3 is a view indicating a relationship between Cge2/Cge1 and the Ic peak. FIG. 3 indicates a ratio of gate-emitter capacitance Cge2 of the electrode connected to the second resistor R2 with respect to gate-emitter capacitance Cge1 of the electrode connected to the first resistor R1 (Cge2/Cge1) on a horizontal axis. The inventor has newly found that the Ic peak can be made smaller by making Cge2/Cge1 smaller. By making Cge2/Cge1 equal to or less than 0.5, the Ic peak can be made smaller by equal to or greater than 30%, and by making Cge2/Cge1 equal to or less than 0.2, the Ic peak can be made smaller by equal to or greater than 40%. Thus, in the present embodiment, the ratio of Cge of the electrode connected to the lower electrode 12 with respect to Cge of the upper electrode 14 is preferably made equal to or less than 0.5 and further preferably made equal to or less than 0.2.

Further, there is a period during which the voltage of the lower electrode 12 is lower than the voltage of the upper electrode 14 during the miller period after the current increase period upon turn-on. The miller period does not affect the Ic peak, and thus, even if the voltage of the lower electrode 12 is low, the Ic peak does not increase. By making the voltage of the lower electrode 12 smaller during the miller period, a voltage to be applied to the gate oxide film can be decreased. It is therefore possible to extend the life of the gate oxide film compared to a case where the voltage of the lower electrode 12 is always high. On the other hand, if there is a period during which the voltage of the lower electrode 12 is higher than the voltage of the upper electrode 14 during the miller period, Cge can be decreased.

FIG. 4 is a cross-sectional view illustrating a relationship of thicknesses of the insulating films of the semiconductor device according to the first embodiment. A thickness T2 of the lower gate insulating film 13 that covers a side surface of the lower electrode 12 and a thickness T4 of the lower gate insulating film 13 that covers a bottom portion of the lower electrode 12 are thicker than a thickness T1 of the upper gate insulating film 15 that covers a side surface of the upper electrode 14. By this means, Cge of the lower electrode 12 becomes smaller than Cge of the upper electrode 14, and thus, the charging speed of the capacitance of the lower electrode 12 becomes higher as described above, so that it is possible to make the voltage of the lower electrode 12 higher and make Cgc smaller, thereby reducing electromagnetic noise.

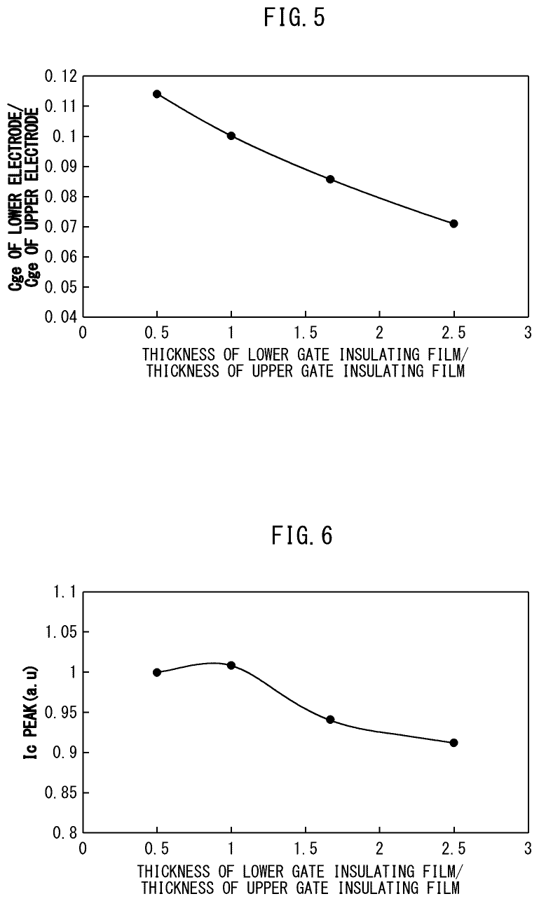

FIG. 5 is a view indicating a relationship between the thickness of the lower gate insulating film/a thickness of the upper gate insulating film and Cge of the lower electrode/Cge of the upper electrode. FIG. 6 is a view indicating a relationship between the thickness of the lower gate insulating film/the thickness of the upper gate insulating film and the Ic peak. To decrease the ratio of Cge of the lower electrode/Cge of the upper electrode to decrease the Ic peak, the thickness of the lower gate insulating film 13 is preferably made equal to or greater than 1.5 times of the thickness of the upper gate insulating film 15, further preferably made equal to or greater than double, and still further preferably made equal to or greater than 2.5 times.

Further, when the potential of the lower electrode 12 becomes high, a potential difference occurs between the upper electrode 14 and the lower electrode 12, and capacitance occurs. Thus, a thickness T3 of the intermediate insulating film 16 is made thicker than the thickness T1 of the upper gate insulating film 15 on the side surface of the upper electrode 14. This decreases Cge of the lower electrode 12, and thus, the charging speed of the capacitance of the lower electrode 12 becomes higher as described above, which makes it possible to make the voltage of the lower electrode 12 higher and make Cge smaller, thereby reducing electromagnetic noise.

Further, a CR time constant comprised of gate capacitance (Cies2=Cge+Cgc) of the lower electrode 12 and the second resistor R2 is smaller than a CR time constant comprised of gate capacitance (Cies1=Cge+Cgc) of the upper electrode 14 and the first resistor R1. This increases the charging speed of the capacitance of the lower electrode 12, so that electromagnetic noise can be reduced.

Further, a resistance value of the second resistor R2 is smaller than a resistance value of the first resistor R1. This increases the charging speed of the capacitance of the lower electrode 12, so that electromagnetic noise can be reduced. On the other hand, if the resistance value of the second resistor R2 is greater than the resistance value of the first resistor R1, rising of the gate voltage determined by the displacement current and electric resistance increases. Thus, the voltage of the lower electrode 12 can be made higher than the voltage of the upper electrode 14, so that Cgc can be decreased.

Further, impurity concentration of the carrier accumulation layer 6 is higher than impurity concentration of the drift layer 2, and thus, the voltage of the lower electrode 12 is easily increased. It is therefore possible to further decrease Cgc and reduce electromagnetic noise by forming the carrier accumulation layer 6.

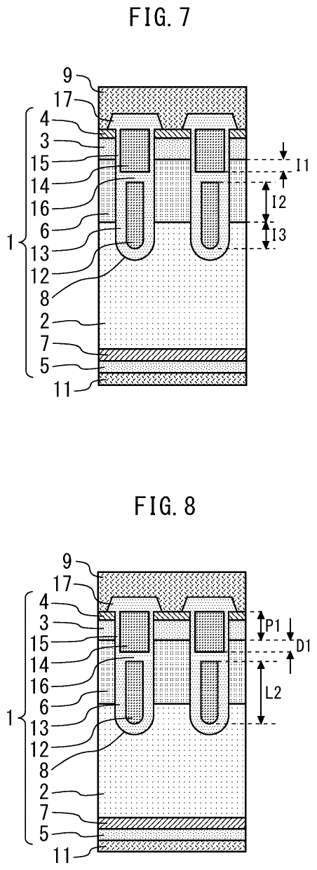

FIG. 7 is a cross-sectional view illustrating a relationship between a length of the carrier accumulation layer and a length of the drift layer in the semiconductor device according to the first embodiment. A length I2 of the carrier accumulation layer 6 facing the lower electrode 12 is longer than a length I1 of the carrier accumulation layer 6 facing the upper electrode 14. By increasing a region where the lower electrode 12 faces the carrier accumulation layer 6, it is possible to increase the voltage of the lower electrode 12 and decrease Cgc. By reducing a region where the upper electrode 14 faces the carrier accumulation layer 6, it is possible to decrease Cgc of the upper electrode.

Further, the length I2 of the carrier accumulation layer 6 facing the side surface of the lower electrode 12 is longer than a length I3 of the drift layer 2 facing the side surface of the lower electrode 12. Impurity concentration of the carrier accumulation layer 6 is higher than impurity concentration of the drift layer 2, and thus, the voltage of the lower electrode 12 is easily increased. Thus, by increasing a region where the lower electrode 12 faces the carrier accumulation layer 6, it is possible to increase the voltage of the lower electrode 12 and decrease Cgc.

FIG. 8 is a cross-sectional view illustrating a relationship between the lengths of the lower electrode and the upper electrode and a depth of the base layer in the semiconductor device according to the first embodiment. Cgc depends on an area of the electrode facing the drift layer 2 and the carrier accumulation layer 6, and thus, a length D1 of the upper electrode 14 extending below the base layer 3 is proportional to Cgc of the upper electrode 14, and a length L2 of the lower electrode 12 is proportional to Cgc of the lower electrode 12. In the present embodiment, the length L2 is longer than the length D1. A depth P1 of the base layer 3 is longer than the length D1.

In a region below the base layer 3 where the voltage changes, by shortening an overhang length D1 of the upper electrode 14 at a low voltage, the depletion layer can be extended, so that Cgc of the upper electrode 14 can be decreased, and a peak current Ic can be reduced. To sufficiently decrease Cgc of the upper electrode 14, the overhang length D1 of the upper electrode 14 is preferably made equal to or less than half the length L2 of the lower electrode 12, and further preferably made equal to or less than ⅓.

### Second Embodiment

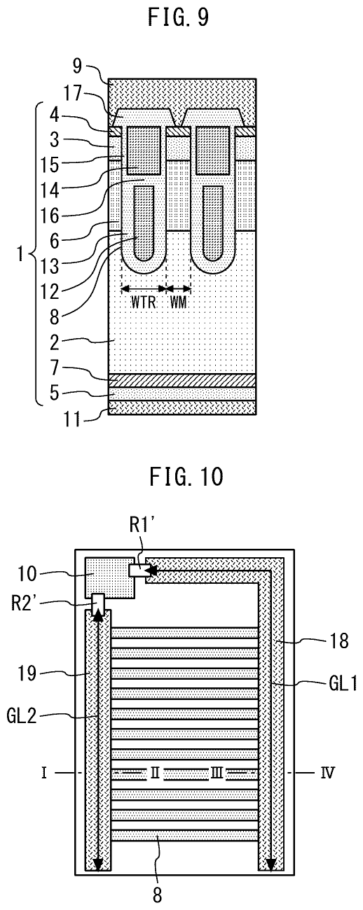

FIG. 9 is a cross-sectional view illustrating a semiconductor device according to a second embodiment. A plurality of trenches 8 are formed on the semiconductor substrate 1 side-by-side. A mesa width WM between the adjacent trenches 8 is narrower than a width WTR of the trench 8. This can increase the voltage of the mesa portion and decrease Cgc, so that it is possible to reduce electromagnetic noise. Other configurations and effects are similar to those of the first embodiment.

### Third Embodiment

FIG. 10 is a top view illustrating a semiconductor device according to a third embodiment. A first gate wiring 18 and a resistor R1′ connect the upper electrode 14 and the gate electrode 10. A second gate wiring 19 and a resistor R2′ connect the lower electrode 12 and the gate electrode 10. The first resistor R1 is a sum of resistance of the resistor R1′ and the first gate wiring 18. The second resistor R2 is a sum of resistance of the resistor R2′ and the second gate wiring 19. A length GL2 of the second gate wiring 19 is shorter than a length GL1 of the first gate wiring 18. Thus, even if a resistance value of the resistor R1′ is the same as a resistance value of the resistor R2′, the resistance value of the second resistor R2 is smaller than the resistance value of the first resistor R1. This increases the charging speed of the capacitance of the lower electrode 12, so that it is possible to reduce electromagnetic noise.

On the other hand, if the length GL2 of the second gate wiring 19 is longer than the length GL1 of the first gate wiring 18, the resistance value of the second resistor R2 becomes greater. Thus, rising of the gate voltage determined by the displacement current and electric resistance increases, so that the voltage of the lower electrode 12 can be made higher than the voltage of the upper electrode 14, and Cgc can be decreased.

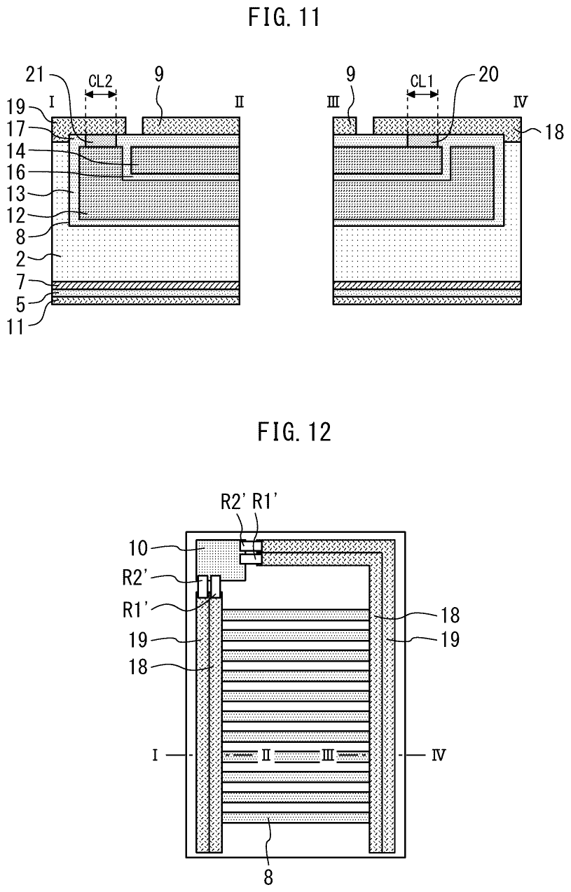

FIG. 11 is a cross-sectional view illustrating a cross-section along I-II and a cross-section along III-IV in FIG. 10. The upper electrode 14 is connected to the first gate wiring 18 via a first gate contact 20. The lower electrode 12 is connected to the second gate wiring 19 via a second gate contact 21. Other configurations and effects are similar to those of the first embodiment.

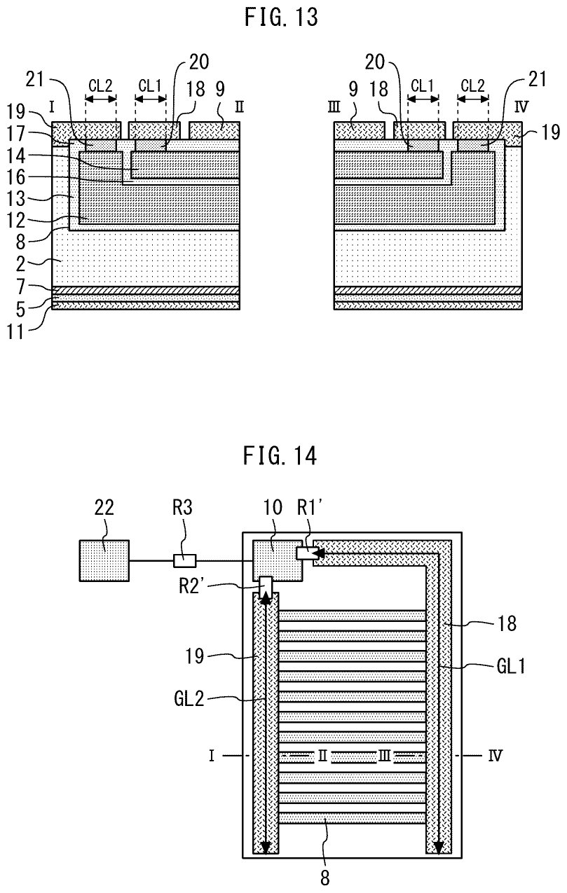

FIG. 12 is a top view illustrating a modification of the semiconductor device according to the third embodiment. FIG. 13 is a cross-sectional view illustrating a cross-section along I-II and a cross-section along III-IV in FIG. 12. The upper electrode 14 is connected to the first gate wiring 18 via a plurality of first gate contacts 20. The lower electrode 12 is connected to the second gate wiring 19 via a plurality of second gate contacts 21. Further, by forming the first gate wiring 18 and the second gate wiring 19 doubly in a peripheral portion of the substrate and inside thereof, it is possible to increase contact portions with the upper electrode 14 or the lower electrode 12. This enables gate operation without a gate delay in a chip plane.

### Fourth Embodiment

FIG. 14 is a view illustrating a semiconductor device according to a fourth embodiment. A gate power supply 22 supplies power to the gate electrode 10. A gate resistor R3 is connected between the gate power supply 22 and the gate electrode 10 to adjust the switching speed. The gate resistor R3 has a resistance value greater than the resistance values of the first resistor R1 and the second resistor R2. If large electric resistance is formed inside the chip, an energized region is reduced, conduction loss increases, and an element size and manufacturing cost also increase. To avoid this, the gate resistor R3 is formed outside the semiconductor substrate 1. This can reduce a resistance region within the substrate, so that it is possible to reduce conduction loss, an element size and manufacturing cost. Other configurations and effects are similar to those of the first embodiment.

### Fifth Embodiment

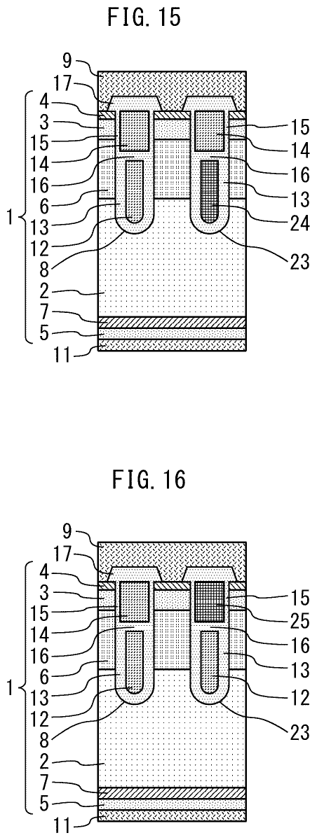

FIG. 15 is a cross-sectional view illustrating a semiconductor device according to a fifth embodiment. A plurality of trenches 8 and a plurality of dummy trenches 23 are formed on the semiconductor substrate 1 side-by-side. The dummy trenches 23 penetrate the source layer 4 and the base layer 3 from the upper surface of the semiconductor substrate 1 in a similar manner to the trenches 8. The dummy trenches 23 have the same depth and width as those of the trenches 8.

A dummy lower electrode 24 is formed inside each of the dummy trenches 23 via the lower gate insulating film 13. The dummy lower electrode 24 is connected to the emitter electrode 9. A material, a length, a width, and the like, of the dummy lower electrode 24 are the same as those of the lower electrode 12. The upper electrode 14 is formed inside each of the dummy trenches 23 via the upper gate insulating film 15, positioned above the dummy lower electrode 24, and separated from the dummy lower electrode 24 by the intermediate insulating film 16.

By forming the dummy lower electrode 24, a ratio of the lower electrode 12 connected to the gate electrode 10 is reduced, and a ratio of the dummy lower electrode 24 connected to the emitter electrode 9 increases in the whole of the plurality of trenches including the trenches 8 and the dummy trenches 23. It is therefore possible to reduce gate capacitance parasitic in the lower electrode 12. This can increase the charging speed of the capacitance of the lower electrode 12, increase the voltage of the lower electrode 12, and decrease Cgc. Other configurations and effects are similar to those of the first embodiment.

### Sixth Embodiment

FIG. 16 is a cross-sectional view illustrating a semiconductor device according to a sixth embodiment. The dummy upper electrode 25 is formed inside each of the dummy trenches 23 via the upper gate insulating film 15. A material, a length, a width, and the like, of the dummy upper electrode 25 are the same as those of the upper electrode 14. The lower electrode 12 is formed inside each of the dummy trenches 23 via the lower gate insulating film 13, positioned below the dummy upper electrode 25, and separated from the dummy upper electrode 25 via the intermediate insulating film 16. By forming the dummy upper electrode 25, Cge that becomes coupling capacitance between the upper electrode 14 and the dummy upper electrode 25 occurs. Increase of the gate voltage of the upper electrode 14 can be reduced by this coupling capacitance, so that it is possible to reduce electromagnetic noise. Other configurations and effects are similar to those of the fifth embodiment.

### Seventh Embodiment

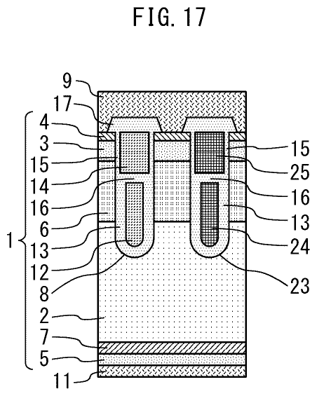

FIG. 17 is a cross-sectional view illustrating a semiconductor device according to a seventh embodiment. The dummy lower electrode 24 in the fifth embodiment and the dummy upper electrode 25 in the sixth embodiment are formed in each of the dummy trenches 23. In the fifth embodiment, Cge is parasitic between the upper electrode 14 and the dummy lower electrode 24. On the other hand, in the present embodiment, Cge can be decreased by providing dummy electrodes as both the upper and lower electrodes, so that it is possible to reduce gate capacitance parasitic in the lower electrode 12 compared to the fifth embodiment. It is therefore possible to increase the charging speed of the capacitance of the lower electrode 12, increase the voltage of the lower electrode 12 and decrease Cgc. Other configurations and effects are similar to those of the fifth embodiment.

The semiconductor substrate 1 is not limited to a substrate formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A semiconductor device comprising:
a semiconductor substrate including a drift layer of a first conductive type, a base layer of second conductive type formed on the drift layer, a source layer of a first conductive type formed on the base layer, and a collector layer of second conductive type formed below the drift layer;
an emitter electrode formed on an upper surface of the semiconductor substrate and connected to the base layer and the source layer;
a gate electrode formed on the upper surface of the semiconductor substrate;
a collector electrode formed on a lower surface of the semiconductor substrate and connected to the collector layer;
a lower electrode formed inside a trench penetrating the source layer and the base layer from the upper surface of the semiconductor substrate via a lower gate insulating film;
an upper electrode formed inside the trench via an upper gate insulating film, positioned above the lower electrode and separated from the lower electrode by an intermediate insulating film;
a first resistor connected between the upper electrode and the gate electrode; and
a second resistor connected between the lower electrode and the gate electrode,
wherein gate-emitter capacitance of the lower electrode is smaller than gate-emitter capacitance of the upper electrode.

### (Supplementary Note 2)

The semiconductor device according to Supplementary Note 1, wherein there is a period during which a voltage of the lower electrode is higher than a voltage of the upper electrode during a current increase period upon turn-on.

### (Supplementary Note 3)

The semiconductor device according to Supplementary Note 1 or 2, wherein a ratio of gate-emitter capacitance of the lower electrode with respect to gate-emitter capacitance of the upper electrode is equal to or less than 0.5.

### (Supplementary Note 4)

The semiconductor device according to Supplementary Note 1 or 2, wherein a ratio of gate-emitter capacitance of the lower electrode with respect to gate-emitter capacitance of the upper electrode is equal to or less than 0.2.

### (Supplementary Note 5)

The semiconductor device according to any one of Supplementary Notes 1 to 4, wherein there is a period during which a voltage of the lower electrode is lower than a voltage of the upper electrode during a miller period upon turn-on.

### (Supplementary Note 6)

The semiconductor device according to any one of Supplementary Notes 1 to 5, wherein a thickness of the lower gate insulating film that covers a side surface and a bottom portion of the lower electrode is thicker than a thickness of the upper gate insulating film that covers a side surface of the upper electrode.

### (Supplementary Note 7)

The semiconductor device according to Supplementary Note 6, wherein a thickness of the lower gate insulating film is equal to or greater than 1.5 times of a thickness of the upper gate insulating film.

### (Supplementary Note 8)

The semiconductor device according to Supplementary Note 6, wherein a thickness of the lower gate insulating film is equal to or greater than 2 times of a thickness of the upper gate insulating film.

### (Supplementary Note 9)

The semiconductor device according to Supplementary Note 6, wherein a thickness of the lower gate insulating film is equal to or greater than 2.5 times of a thickness of the upper gate insulating film.

### (Supplementary Note 10)

The semiconductor device according to any one of Supplementary Notes 1 to 9, wherein a thickness of the intermediate insulating film is thicker than a thickness of the upper gate insulating film on a side surface of the upper electrode.

### (Supplementary Note 11)

The semiconductor device according to any one of Supplementary Notes 1 to 10, wherein a CR time constant comprised of gate capacitance of the lower electrode and the second resistor is smaller than a CR time constant comprised of gate capacitance of the upper electrode and the first resistor.

### (Supplementary Note 12)

The semiconductor device according to any one of Supplementary Notes 1 to 11, wherein a resistance value of the second resistor is smaller than a resistance value of the first resistor.

### (Supplementary Note 13)

The semiconductor device according to any one of Supplementary Notes 1 to 11, wherein a resistance value of the second resistor is larger than a resistance value of the first resistor.

### (Supplementary Note 14)

The semiconductor device according to any one of Supplementary Notes 1 to 13, further comprising a carrier accumulation layer of a first conductive type formed between the drift layer and the base layer and having higher impurity concentration than that of the drift layer.

### (Supplementary Note 15)

The semiconductor device according to Supplementary Note 14, wherein a length of the carrier accumulation layer facing a side surface of the lower electrode is longer than a length of the carrier accumulation layer facing a side surface of the upper electrode.

### (Supplementary Note 16)

The semiconductor device according to Supplementary Note 14 or 15, wherein a length of the carrier accumulation layer facing a side surface of the lower electrode is longer than a length of the drift layer facing a side surface of the lower electrode.

### (Supplementary Note 17)

The semiconductor device according to any one of Supplementary Notes 11 to 16, wherein a length of the lower electrode is longer than a length of the upper electrode extending below the base layer.

### (Supplementary Note 18)

The semiconductor device according to any one of Supplementary Notes 11 to 17, wherein a depth of the base layer is longer than a length of the upper electrode extending below the base layer.

### (Supplementary Note 19)

The semiconductor device according to any one of Supplementary Notes 1 to 18, wherein a plurality of the trenches are formed on the semiconductor substrate side-by-side, and
a mesa width between the adjacent trenches is narrower than a width of the trench.

### (Supplementary Note 20)

The semiconductor device according to any one of Supplementary Notes 1 to 19, further comprising a first gate wiring connecting the upper electrode and the gate electrode, and a second gate wiring connecting the lower electrode and the gate electrode,
wherein a length of the second gate wiring is shorter than a length of the first gate wiring.

### (Supplementary Note 21)

The semiconductor device according to any one of Supplementary Notes 1 to 19, further comprising a first gate wiring connecting the upper electrode and the gate electrode, and a second gate wiring connecting the lower electrode and the gate electrode,
wherein a length of the second gate wiring is longer than a length of the first gate wiring.

### (Supplementary Note 22)

The semiconductor device according to Supplementary Note 20 or 21, wherein the upper electrode is connected to the first gate wiring via a first gate contact, and
the lower electrode is connected to the second gate wiring via a second gate contact.

### (Supplementary Note 23)

The semiconductor device according to any one of Supplementary Notes 1 to 22, further comprising a gate power supply supplying power to the gate electrode, and
a gate resistor connected between the gate power supply and the gate electrode,
wherein the gate resistor has a resistance value greater than resistance values of the first resistor and the second resistor and is formed outside the semiconductor substrate.

### (Supplementary Note 24)

The semiconductor device according to any one of Supplementary Notes 1 to 23, further comprising a dummy lower electrode formed inside a dummy trench penetrating the source layer and the base layer from the upper surface of the semiconductor substrate via the lower gate insulating film and connected to the emitter electrode,
wherein the upper electrode is formed inside the dummy trench via the upper gate insulating film, positioned above the dummy lower electrode, and separated from the dummy lower electrode by the intermediate insulating film.

### (Supplementary Note 25)

The semiconductor device according to any one of Supplementary Notes 1 to 23, further comprising a dummy upper electrode formed inside a dummy trench penetrating the source layer and the base layer from the upper surface of the semiconductor substrate via the upper gate insulating film and connected to the emitter electrode,
wherein the lower electrode is formed inside the dummy trench via the lower gate insulating film, positioned below the dummy upper electrode, and separated from the dummy upper electrode via the intermediate insulating film.

### (Supplementary Note 26)

The semiconductor device according to any one of Supplementary Notes 1 to 23, further comprising a dummy lower electrode formed inside a dummy trench penetrating the source layer and the base layer from the upper surface of the semiconductor substrate via the lower gate insulating film and connected to the emitter electrode, and
a dummy upper electrode formed inside the dummy trench via the upper gate insulating film, positioned above the dummy lower electrode and separated from the dummy lower electrode by the intermediate insulating film.

### (Supplementary Note 27)

The semiconductor device according to any one of Supplementary Notes 1 to 26, wherein the semiconductor substrate is formed of a wide-bandgap semiconductor.

### REFERENCE SIGNS LIST

1 semiconductor substrate; 2 drift layer; 3 base layer; 4 source layer; 5 collector layer; 6 carrier accumulation layer; 8 trench; 9 emitter electrode; 10 gate electrode; 11 collector electrode; 12 lower electrode; 13 lower gate insulating film; 14 upper electrode; 15 upper gate insulating film; 16 intermediate insulating film; 18 first gate wiring; 19 second gate wiring; 20 first gate contact; 21 second gate contact; 22 gate power supply; 23 dummy trench; 24 dummy lower electrode; 25 dummy upper electrode; R1 first resistor; R2 second resistor; R3 gate resistor

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-080264, filed on May 16, 2024 including specification, claims, drawings and summary, on which the convention priority of the present application is based, is incorporated herein by reference in its entirety.

1. A semiconductor device comprising:
a semiconductor substrate including a drift layer of a first conductive type, a base layer of second conductive type formed on the drift layer, a source layer of a first conductive type formed on the base layer, and a collector layer of second conductive type formed below the drift layer;
an emitter electrode formed on an upper surface of the semiconductor substrate and connected to the base layer and the source layer;
a gate electrode formed on the upper surface of the semiconductor substrate;
a collector electrode formed on a lower surface of the semiconductor substrate and connected to the collector layer;
a lower electrode formed inside a trench penetrating the source layer and the base layer from the upper surface of the semiconductor substrate via a lower gate insulating film;
an upper electrode formed inside the trench via an upper gate insulating film, positioned above the lower electrode and separated from the lower electrode by an intermediate insulating film;
a first resistor connected between the upper electrode and the gate electrode; and
a second resistor connected between the lower electrode and the gate electrode,
wherein gate-emitter capacitance of the lower electrode is smaller than gate-emitter capacitance of the upper electrode.

2. The semiconductor device according to claim 1, wherein there is a period during which a voltage of the lower electrode is higher than a voltage of the upper electrode during a current increase period upon turn-on.

3. The semiconductor device according to claim 1, wherein a ratio of gate-emitter capacitance of the lower electrode with respect to gate-emitter capacitance of the upper electrode is equal to or less than 0.5.

4. The semiconductor device according to claim 1, wherein a ratio of gate-emitter capacitance of the lower electrode with respect to gate-emitter capacitance of the upper electrode is equal to or less than 0.2.

5. The semiconductor device according to claim 1, wherein there is a period during which a voltage of the lower electrode is lower than a voltage of the upper electrode during a miller period upon turn-on.

6. The semiconductor device according to claim 1, wherein a thickness of the lower gate insulating film that covers a side surface and a bottom portion of the lower electrode is thicker than a thickness of the upper gate insulating film that covers a side surface of the upper electrode.

7. The semiconductor device according to claim 6, wherein a thickness of the lower gate insulating film is equal to or greater than 1.5 times of a thickness of the upper gate insulating film.

8. The semiconductor device according to claim 6, wherein a thickness of the lower gate insulating film is equal to or greater than 2 times of a thickness of the upper gate insulating film.

9. The semiconductor device according to claim 6, wherein a thickness of the lower gate insulating film is equal to or greater than 2.5 times of a thickness of the upper gate insulating film.

10. The semiconductor device according to claim 1, wherein a thickness of the intermediate insulating film is thicker than a thickness of the upper gate insulating film on a side surface of the upper electrode.

11. The semiconductor device according to claim 1, wherein a CR time constant comprised of gate capacitance of the lower electrode and the second resistor is smaller than a CR time constant comprised of gate capacitance of the upper electrode and the first resistor.

12. The semiconductor device according to claim 1, wherein a resistance value of the second resistor is smaller than a resistance value of the first resistor.

13. The semiconductor device according to claim 1, wherein a resistance value of the second resistor is larger than a resistance value of the first resistor.

14. The semiconductor device according to claim 1, further comprising a carrier accumulation layer of a first conductive type formed between the drift layer and the base layer and having higher impurity concentration than that of the drift layer.

15. The semiconductor device according to claim 14, wherein a length of the carrier accumulation layer facing a side surface of the lower electrode is longer than a length of the carrier accumulation layer facing a side surface of the upper electrode.

16. The semiconductor device according to claim 14, wherein a length of the carrier accumulation layer facing a side surface of the lower electrode is longer than a length of the drift layer facing a side surface of the lower electrode.

17. The semiconductor device according to claim 1, wherein a length of the lower electrode is longer than a length of the upper electrode extending below the base layer.

18. The semiconductor device according to claim 1, wherein a depth of the base layer is longer than a length of the upper electrode extending below the base layer.

19. The semiconductor device according to claim 1, wherein a plurality of the trenches are formed on the semiconductor substrate side-by-side, and
a mesa width between the adjacent trenches is narrower than a width of the trench.

20. The semiconductor device according to claim 1, further comprising a first gate wiring connecting the upper electrode and the gate electrode, and a second gate wiring connecting the lower electrode and the gate electrode,
wherein a length of the second gate wiring is shorter than a length of the first gate wiring.

21. The semiconductor device according to claim 1, further comprising a first gate wiring connecting the upper electrode and the gate electrode, and a second gate wiring connecting the lower electrode and the gate electrode,
wherein a length of the second gate wiring is longer than a length of the first gate wiring.

22. The semiconductor device according to claim 20, wherein the upper electrode is connected to the first gate wiring via a first gate contact, and
the lower electrode is connected to the second gate wiring via a second gate contact.

23. The semiconductor device according to claim 1, further comprising a gate power supply supplying power to the gate electrode, and
a gate resistor connected between the gate power supply and the gate electrode,
wherein the gate resistor has a resistance value greater than resistance values of the first resistor and the second resistor and is formed outside the semiconductor substrate.

24. The semiconductor device according to claim 1, further comprising a dummy lower electrode formed inside a dummy trench penetrating the source layer and the base layer from the upper surface of the semiconductor substrate via the lower gate insulating film and connected to the emitter electrode,
wherein the upper electrode is formed inside the dummy trench via the upper gate insulating film, positioned above the dummy lower electrode, and separated from the dummy lower electrode by the intermediate insulating film.

25. The semiconductor device according to claim 1, further comprising a dummy upper electrode formed inside a dummy trench penetrating the source layer and the base layer from the upper surface of the semiconductor substrate via the upper gate insulating film and connected to the emitter electrode,
wherein the lower electrode is formed inside the dummy trench via the lower gate insulating film, positioned below the dummy upper electrode, and separated from the dummy upper electrode via the intermediate insulating film.

26. The semiconductor device according to claim 1, further comprising a dummy lower electrode formed inside a dummy trench penetrating the source layer and the base layer from the upper surface of the semiconductor substrate via the lower gate insulating film and connected to the emitter electrode, and
a dummy upper electrode formed inside the dummy trench via the upper gate insulating film, positioned above the dummy lower electrode and separated from the dummy lower electrode by the intermediate insulating film.

27. The semiconductor device according to claim 1, wherein the semiconductor substrate is formed of a wide-bandgap semiconductor.
